(19) United States
(12) Patent Application Publication
(10) Pub. No.: US 2025/0338519 A1
(43) Pub. Date: Oct. 30, 2025

(54) SEMICONDUCTOR DEVICE, SEMICONDUCTOR PACKAGING AND INVERTER SYSTEMS

(71) Applicant: Renesas Electronics Corporation, Tokyo (JP)

(72) Inventors: Yasutaka NAKASHIBA, Tokyo (JP); Takayuki IGARASHI, Tokyo (JP); Tatsuo KASAOKA, Tokyo (JP)

(21) Appl. No.: 19/084,002

(22) Filed: Mar. 19, 2025

(30) Foreign Application Priority Data
Apr. 30, 2024 (JP) 2024-073588

(51) Int. Cl. H10D 1/20; H01F 38/14; H01L 23/00; H01L 23/528; H01L 25/18; H10D 84/83

(52) U.S. Cl. CPC H10D 1/20; H01F 38/14; H01L 23/528; H01L 25/18; H01L 24/48; H01L 2224/48137; H10D 84/83

(57) ABSTRACT

The semiconductor device includes first, second and third semiconductor chips. Through non-contact communication between different potentials in the third semiconductor chip, signal transmission and reception occur between the first and second semiconductor chips. The first semiconductor chip comprises a first semiconductor substrate and a first active element. The first semiconductor substrate has a first main surface. The first active element is formed on the first main surface. The second semiconductor chip comprises a second semiconductor substrate and a second active element. The second semiconductor substrate has a second main surface. The second active element is formed on the second main surface. The third semiconductor chip comprises a third semiconductor substrate and a passive element. The third semiconductor substrate has a third main surface. The passive element is formed above the third main surface. Each of the first, second and third semiconductor substrates is formed of monocrystalline silicon.

### CROSS-REFERENCE TO RELATED APPLICATIONS

The disclosure of Japanese Patent Application No. 2024-073588 filed on Apr. 30, 2024, including the specification, drawings and abstract is incorporated herein by reference in its entirety.

### BACKGROUND

The present disclosure relates to a semiconductor device, a semiconductor package, and an inverter system.

The semiconductor device described in Japanese Patent Laid-Open No. 2023-157045 (Patent Document 1) includes a first semiconductor chip, a second semiconductor chip, and a third semiconductor chip. The first and second semiconductor chips each have a first circuit and a second circuit, respectively. The third semiconductor chip includes a transformer. The transformer performs signal transmission and reception between the first circuit and the second circuit through non-contact communication between different potentials.

### SUMMARY

In the semiconductor device described in Patent Document 1, the third semiconductor chip tends to warp more easily compared to the first and second semiconductor chips. Other problems and novel features will become apparent from the description of this specification and the accompanying drawings.

The semiconductor device of the present disclosure includes a first semiconductor chip, a second semiconductor chip, and a third semiconductor chip. Signal transmission and reception between the first semiconductor chip and the second semiconductor chip are performed through non-contact communication between different potentials in the third semiconductor chip. The includes a first semiconductor substrate and a first active element. The first semiconductor substrate has a first main surface, and the first active element is formed on the first main surface. The second semiconductor chip includes a second semiconductor substrate and a second active element. The second semiconductor substrate has a second main surface, and the second active element is formed on the second main surface. The third semiconductor chip includes a third semiconductor substrate and a passive element. The third semiconductor substrate has a third main surface, and the passive element is formed above the third main surface. Each of the first, second, and third semiconductor substrates is formed of monocrystalline silicon. A lattice plane spacing parallel to the third main surface in the third semiconductor substrate is smaller than a lattice plane spacing parallel to the first main surface in the first semiconductor substrate and a lattice plane spacing parallel to the second main surface in the second semiconductor substrate.

According to the semiconductor device of the present disclosure, it is possible to reduce the warping of the third semiconductor chip.

### BRIEF DESCRIPTION OF THE DRAWINGS

FIG. 1 is a block diagram of a semiconductor device DEV.

FIG. 2 is an explanatory diagram showing an example of signal transmission from a control circuit CC to a drive circuit DR.

FIG. 3 is a cross-sectional view of a semiconductor chip CHP1.

FIG. 4 is a cross-sectional view of a semiconductor chip CHP2.

FIG. 5 is a first plan view of a semiconductor chip CHP3.

FIG. 6 is a second plan view of the semiconductor chip CHP3.

FIG. 7 is a third plan view of the semiconductor chip CHP3.

FIG. 8 is a cross-sectional view in VIII-VIII in FIG. 7.

FIG. 9 is a flow chart for manufacturing the semiconductor chip CHP1.

FIG. 10 is a cross-sectional view for explaining an ion-implantation step S2.

FIG. 11 is a cross-sectional view for explaining a trench formation step S3.

FIG. 12 is a cross-sectional view for explaining an element isolation film formation step S4.

FIG. 13 is a cross-sectional view for explaining a gate insulating film formation step S5.

FIG. 14 is a cross-sectional view for explaining a gate electrode formation step S6.

FIG. 15 is a cross-sectional view for explaining an ion-implantation step S7.

FIG. 16 is a cross-sectional view for explaining a sidewall spacer formation step S8.

FIG. 17 is a cross-sectional view for explaining an ion-implantation step S9.

FIG. 18 is a cross-sectional view for explaining an interlayer insulating film formation step S10.

FIG. 19 is a cross-sectional view for explaining a contact plug formation step S11.

FIG. 20 is a cross-sectional view for explaining a wiring layer formation step S12.

FIG. 21 is a cross-sectional view for explaining an interlayer insulating film formation step S13.

FIG. 22 is a cross-sectional view for explaining a via plug formation step S14.

FIG. 23 is a cross-sectional view for explaining a wiring layer formation step S15.

FIG. 24 is a schematic graph showing the relationship between a progress stage of the manufacturing process and an amount of wafer warpage in the semiconductor chip CHP3.

FIG. 25 is a cross-sectional view of the semiconductor chip CHP3 in the semiconductor device DEV according to the first modified example.

FIG. 26 is a cross-sectional view of a semiconductor package PKG.

FIG. 27 is a schematic diagram of an inverter system INVS.

### DETAILED DESCRIPTION

The details of the embodiments of the present disclosure will be described with reference to the drawings. In the following drawings, the same or corresponding parts are denoted by the same reference numerals, and redundant descriptions will not be repeated.

### First Embodiment

A semiconductor device (semiconductor device DEV) according to the first embodiment will be described.

### (Configuration of Semiconductor Device DEV)

The configuration of the semiconductor device DEV will be described below.

### (Outline Configuration of Semiconductor Device DEV)

The outline configuration of the semiconductor device DEV will be described below.

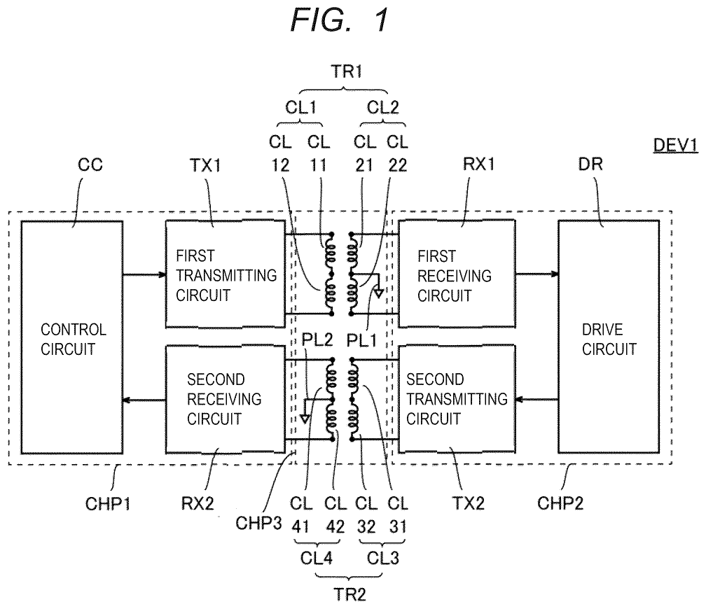

FIG. 1 is a block diagram of the semiconductor device DEV. As shown in FIG. 1, the semiconductor device DEV includes semiconductor chips CHP1, CHP2, and CHP3. The semiconductor chip CHP1 includes a transmitting circuit TX1 and a receiving circuit RX2, and the transmitting circuit TX1 and the receiving circuit RX2 are electrically connected to a control circuit CC. The semiconductor chip CHP2 includes a drive circuit DR, a receiving circuit RX1, and a transmitting circuit TX2. The drive circuit DR is electrically connected to the receiving circuit RX1 and the transmitting circuit TX2.

The semiconductor chip CHP3 includes transformers TR1 and TR2, and lead-out wirings PL1 and PL2.

The transformer TR1 includes a transmitting coil CL1 and a receiving coil CL2. The transmitting coil CL1 includes coils CL11 and CL12, and the receiving coil CL2 includes coils CL21 and CL22. The transmitting coil CL1 and the receiving coil CL2 are electrically connected to the transmitting circuit TX1 and the receiving circuit RX1, respectively.

More specifically, one end of the coil CL11 is electrically connected to the transmitting circuit TX1, and the other end of the coil CL11 is electrically connected to one end of the coil CL12, and the other end of the coil CL12 is electrically connected to the transmitting circuit TX1. One end of the coil CL21 is electrically connected to the receiving circuit RX1, and the other end of the coil CL21 is electrically connected to one end of the coil CL22 via the lead-out wiring PL1, and the other end of the coil CL22 is electrically connected to the receiving circuit RX1.

The transformer TR2 includes a transmitting coil CL3 and a receiving coil CL4. The transmitting coil CL3 includes coils CL31 and CL32, and the receiving coil CL4 includes coils CL41 and CL42. The transmitting coil CL3 and the receiving coil CL4 are electrically connected to the transmitting circuit TX2 and the receiving circuit RX2, respectively.

More specifically, one end of the coil CL31 is electrically connected to the transmitting circuit TX2, and the other end of the coil CL31 is electrically connected to one end of the coil CL32, and the other end of the coil CL32 is electrically connected to the transmitting circuit TX2. One end of the coil CL41 is electrically connected to the receiving circuit RX2, and the other end of the coil CL41 is electrically connected to one end of the coil CL42 via the lead-out wiring PL2, and the other end of the coil CL42 is electrically connected to the receiving circuit RX2.

In the semiconductor device DEV, signals are transmitted from the control circuit CC to the drive circuit DR via the transmitting circuit TX1, the transformer TR1, and the receiving circuit RX1. Also, in the semiconductor device DEV, signals are transmitted from the drive circuit DR to the control circuit CC via the transmitting circuit TX2, the transformer TR2, and the receiving circuit RX2.

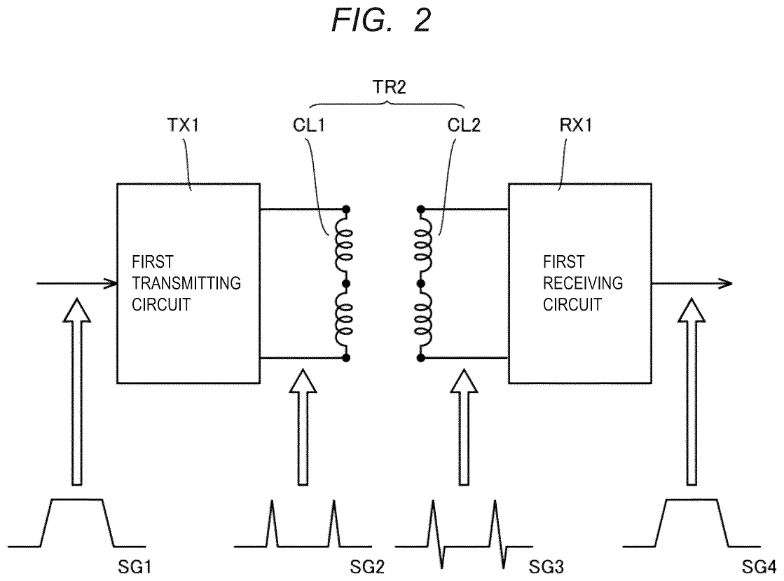

FIG. 2 is an explanatory diagram showing an example of signal transmission from the control circuit CC to the drive circuit DR. As shown in FIG. 2, the control circuit CC inputs a signal SG1 to the transmitting circuit TX1. The signal SG1 is a square wave. The transmitting circuit TX1 modulates the signal SG1 into a signal SG2 and sends the signal SG2 to the transmitting coil CL1. When the signal SG2 flows into the transmitting coil CL1, a signal SG3 corresponding to the signal SG2 flows into the receiving coil CL2 by induced electromotive force. The receiving circuit RX1 amplifies the signal SG3 and demodulates it into a signal SG4 (square wave), which is then output to the drive circuit DR. In this way, signals are transmitted from the control circuit CC to the drive circuit DR. Similarly, signal transmission from the drive circuit DR to the control circuit CC is also performed. Thus, in the semiconductor device DEV, signal transmission between the transmitting circuit TX1 and the receiving circuit RX1 and between the transmitting circuit TX2 and the receiving circuit RX2 is performed by a pulse communication method.

### (Details of Semiconductor Chip CHP1)

The detailed configuration of the semiconductor chip CHP1 is described below.

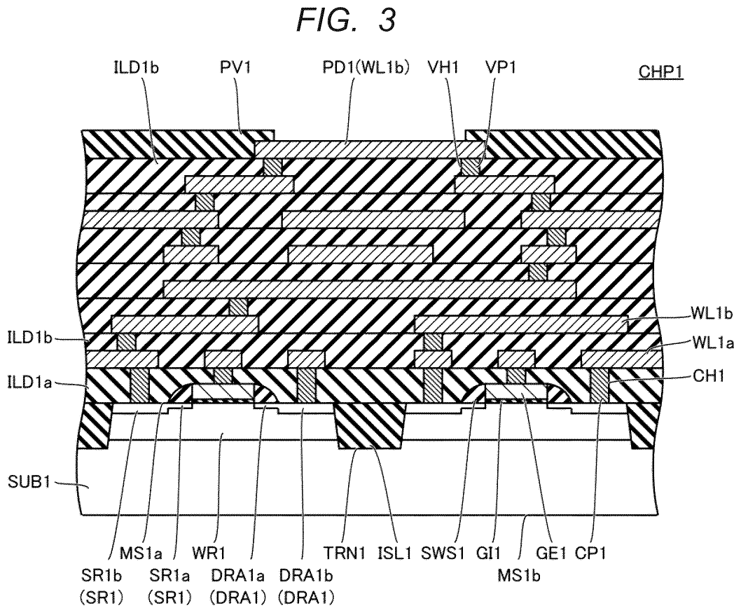

FIG. 3 is a cross-sectional view of the semiconductor chip CHP1. As shown in FIG. 3, the semiconductor chip CHP1 includes a semiconductor substrate SUB1, a gate insulating film GI1, a gate electrode GE1, sidewall spacers SWS1, an element isolation film ISL1, an interlayer insulating film ILD1a, a contact plug CP1, a plurality of interlayer insulating films ILD1b, a wiring layer WL1a, a via plug VP1, a plurality of wiring layers WL1b, and a passivation film PV1.

The semiconductor substrate SUB1 has a main surface MS1a and a main surface MS1b. The main surface MS1b is the opposite side of the main surface MS1a. The main surfaces MS1a and MS1b are end surfaces along a thickness direction of the semiconductor substrate SUB1. The semiconductor substrate SUB1 is formed of monocrystalline silicon. The main surface MS1a is composed of, for example, (100) plane of monocrystalline silicon. However, a crystal face of the monocrystalline silicon constituting the main surface MS1a is not limited to this. Hereinafter, the “(klm) plane” refers to the crystal face of monocrystalline silicon expressed by Miller indices.

The semiconductor substrate SUB1 has a source region SR1, a drain region DRA1, and a well region WR1 formed therein. The source region SR1 and the drain region DRA1 are formed on the main surface MS1a. The source region SR1 and the drain region DRA1 are spaced apart from each other. The source region SR1 includes a first portion SR1a and a second portion SR1b. The drain region DRA1 includes a first portion DRA1a and a second portion DRA1b. The first portion SR1a is positioned closer to the drain region DRA1 than the second portion SR1b, and the first portion DRA1a is positioned closer to the source region SR1 than the second portion DRA1b.

The well region WR1 is formed on the main surface MS1a so as to surround the source region SR1 and the drain region DRA1. The conductivity types of the source region SR1 and the drain region DRA1 are the first conductivity type. The conductivity type of the well region WR1 is the second conductivity type. The second conductivity type is the opposite conductivity type of the first conductivity type. For example, when the first conductivity type is n-type, the second conductivity type is p-type, and when the first conductivity type is p-type, the second conductivity type is n-type. The portion of the well region WR1 between the source region SR1 and the drain region DRA1 is sometimes referred to as the channel region of the well region WR1.

The gate insulating film GIL is formed on the channel region of the well region WR1. The gate insulating film GI1 is formed of, for example, silicon oxide. The gate electrode GE1 is formed on the gate insulating film GI1. The gate electrode GE1 is formed of, for example, polycrystalline silicon doped with impurities. The source region SR1, the drain region DRA1, the well region WR1, the gate insulating film GI1, and the gate electrode GE1 constitute a transistor. This transistor constitutes the transmitting circuit TX1 and the receiving circuit RX2.

A trench TRN1 is formed on the main surface MS1a. The trench TRN1 surrounds the well region WR1 in plan view (when viewed along the normal direction of the main surface MS1a to the semiconductor substrate SUB1). The main surface MS1a is recessed toward the main surface MS1b at the trench TRN1. The element isolation film ISL1 is embedded in the trench TRN1. The element isolation film ISL1 is formed of, for example, silicon oxide. The element isolation film ISL1 electrically separates adjacent transistors.

The sidewall spacers SWS1 are formed on the first portion SR1a and the first portion DRA1a so as to be in contact with side surfaces of the gate insulating film GI1 and the gate electrode GE1. The sidewall spacers SWS1 are formed of, for example, silicon nitride.

The interlayer insulating film ILD1a is formed on the main surface MS1a so as to cover the sidewall spacers SWS1 and the gate electrode GE1. The interlayer insulating film ILD1a is formed of, for example, silicon oxide. A contact hole CH1 is formed in the interlayer insulating film ILD1a. A contact plug CP1 is embedded in the contact hole CH1. The contact plug CP1 is electrically connected to the source region SR1 (second portion SR1b), the drain region DRA1 (second portion DRA1b), or the gate electrode GE1. The contact plug CP1 is formed of, for example, tungsten.

The wiring layer WL1a is formed on the interlayer insulating film ILD1a. The wiring layer WL1a is electrically connected to the contact plug CP1. The wiring layer WL1a is formed of, for example, aluminum or an aluminum alloy.

The plurality of interlayer insulating ILD1b is laminated on the interlayer insulating film ILD1a. The plurality of interlayer insulating films ILD1b is formed of, for example, silicon oxide. The lowermost interlayer insulating film ILD1b covers the wiring layer WL1a. One wiring layer WL1b is formed on one interlayer insulating film ILD1b, and another interlayer insulating film ILD1b is formed on the one interlayer insulating film ILD1b so as to cover the one wiring layer WL1b. However, the uppermost wiring layer WL1b is not covered by the one or another interlayer insulating film ILD1b. One wiring layer WL1a and another wiring layer WL1b on an upper layer of the one wiring layer WL1a are electrically connected by a via plug VP1. The via plug VP1 is embedded in a via hole VH1 formed in the interlayer insulating film ILD1b. The plurality of wiring layers WL1b is formed of, for example, aluminum or an aluminum alloy. The via plug VP1 is formed of, for example, tungsten.

The uppermost wiring layer WL1b has an electrode pad PD1. The electrode pad PD1 is electrically connected to the transistor (transmitting circuit TX1, receiving circuit RX2) through the plurality of wiring layers WL1b, the via plug VP1, the wiring layer WL1a, and the contact plug CP1. The passivation film PV1 is formed on the uppermost interlayer insulating film ILD1b so as to cover the uppermost wiring layer WL1b. An opening is formed in the passivation film PV1. The electrode pad PD1 is exposed from the opening of the passivation film PV1. The passivation film PV1 is formed of, for example, silicon nitride.

### (Details of Semiconductor Chip CHP2)

The detailed configuration of the semiconductor chip CHP2 is described below.

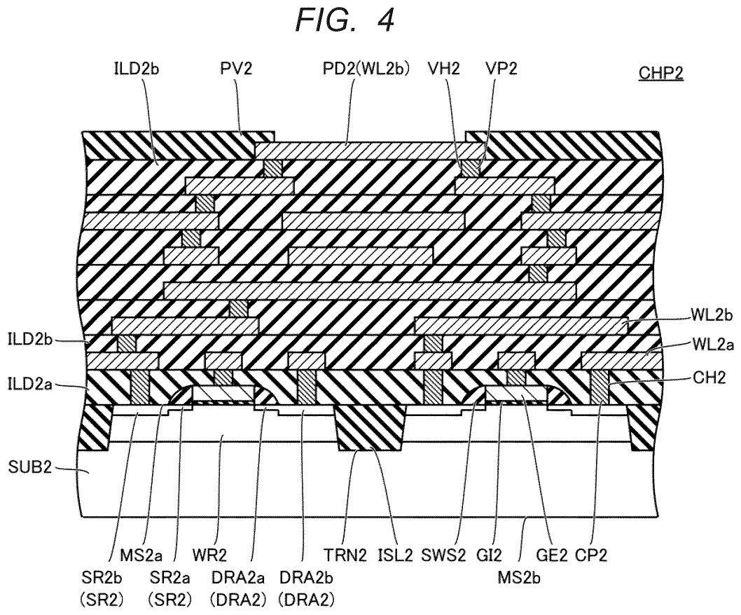

FIG. 4 is a cross-sectional view of the semiconductor chip CHP2. As shown in FIG. 3, the semiconductor chip CHP2 includes a semiconductor substrate SUB2, a gate insulating film GI2, a gate electrode GE2, sidewall spacers SWS2, an element isolation film ISL2, an interlayer insulating film ILD2a, a contact plug CP2, a plurality of interlayer insulating films ILD2b, a wiring layer WL2a, a via plug VP2, a plurality of wiring layers WL2b, and a passivation film PV2.

The semiconductor substrate SUB2 has a main surface MS2a and a main surface MS2b. The main surface MS2b is the opposite side of the main surface MS2a. The main surfaces MS2a and MS2b are end surfaces along the thickness direction of the semiconductor substrate SUB2. The semiconductor substrate SUB2 is formed of monocrystalline silicon. The main surface MS2a is composed of, for example, the (100) plane of monocrystalline silicon. However, the crystal face of the monocrystalline silicon constituting the main surface MS2a is not limited to this.

The semiconductor substrate SUB2 has a source region SR2, a drain region DRA2, and a well region WR2 formed therein. The source region SR2 and the drain region DRA2 are formed on the main surface MS2a. The source region SR2 and the drain region DRA2 are spaced apart from each other. The source region SR2 includes a first portion SR2a and a second portion SR2b. The drain region DRA2 includes a first portion DRA2a and a second portion DRA2b. The first portion SR2a is positioned closer to the drain region DRA2 than the second portion SR2b, and the first portion DRA2a is positioned closer to the source region SR2 than the second portion DRA2b.

The well region WR2 is formed on the main surface MS2a so as to surround the source region SR2 and the drain region DRA2. The conductivity types of the source region SR2 and the drain region DRA2 are the first conductivity type. The conductivity type of the well region WR2 is the second conductivity type. The portion of the well region WR2 between the source region SR2 and the drain region DRA2 is sometimes referred to as the channel region of the well region WR2.

The gate insulating film GI2 is formed on the channel region of the well region WR2. The gate insulating film GI2 is formed of, for example, silicon oxide. The gate electrode GE2 is formed on the gate insulating film GI2. The gate electrode GE2 is formed of, for example, polycrystalline silicon doped with impurities. The source region SR2, the drain region DRA2, the well region WR2, the gate insulating film GI2, and the gate electrode GE2 constitute a transistor. This transistor constitutes the transmitting circuit TX2, the receiving circuit RX1, and the drive circuit DR.

A trench TRN2 is formed on the main surface MS2a. The trench TRN2 surrounds the well region WR2 in plan view (when viewed along the normal direction of the main surface MS2a to the semiconductor substrate SUB2). The main surface MS2a is recessed toward the main surface MS2b at the trench TRN2. The element isolation film ISL2 is embedded in the trench TRN2. The element isolation film ISL2 is formed of, for example, silicon oxide. The element isolation film ISL2 electrically separates adjacent transistors.

The sidewall spacers SWS2 are formed on the first portion SR2a and the first portion DRA2a so as to be in contact with side surfaces of the gate insulating film GI2 and the gate electrode GE2. The sidewall spacers SWS2 are formed of, for example, silicon nitride.

The interlayer insulating film ILD2a is formed on the main surface MS2a so as to cover the sidewall spacers SWS2 and the gate electrode GE2. The interlayer insulating film ILD2a is comprised of, for example, silicon oxide. A contact hole CH2 is formed in the interlayer insulating film ILD2a. The contact plug CP2 is embedded in the contact hole CH2. The contact plug CP2 is electrically connected to the source region SR2 (second portion SR2b), the drain region DRA2 (second portion DRA2b), or the gate electrode GE2. The contact plug CP2 is formed of, for example, tungsten.

The wiring layer WL2a is formed on the interlayer insulating film ILD2a. The wiring layer WL2a is electrically connected to the contact plug CP2. The wiring layer WL2a is formed, for example, of aluminum or an aluminum alloy.

The plurality of interlayer insulating films ILD2b is laminated on the interlayer insulating film ILD2a. The plurality of interlayer insulating films ILD2b is comprised of, for example, silicon oxide. The lowermost interlayer insulating film ILD2b covers the wiring layer WL2a. One wiring layer WL2b is formed on one interlayer insulating film ILD2b, and another interlayer insulating film ILD2b is formed on the one interlayer insulating film ILD2b so as to cover the one wiring layer WL2b. However, the uppermost wiring layer WL2b is not covered by the one or another interlayer insulating film ILD2b. One wiring layer WL2a and another wiring layer WL2b on an upper layer of the one wiring layer WL2a are electrically connected by the via plug VP2. The via plug VP2 is embedded in a via hole VH2 formed in the interlayer insulating film ILD2b. The plurality of wiring layers WL2b is formed, for example, of aluminum or an aluminum alloy. The via plug VP2 is formed, for example, of tungsten.

The uppermost wiring layer WL2b has an electrode pad PD2. The electrode pad PD2 is electrically connected to the transistor (transmitting circuit TX1, receiving circuit RX2, driving circuit DR) through the plurality of wiring layers WL2b, the via plug VP2, the wiring layer WL2a, and the contact plug CP2. The passivation film PV2 is formed on the uppermost interlayer insulating film ILD2b so as to cover the uppermost wiring layer WL2b. An opening is formed in the passivation film PV2. The electrode pad PD2 is exposed from the opening of the passivation film PV2. The passivation film PV2 is formed, for example, of silicon nitride.

### (Detailed Configuration of Semiconductor Chip CHP3)

The detailed configuration of the semiconductor chip CHP3 is described below.

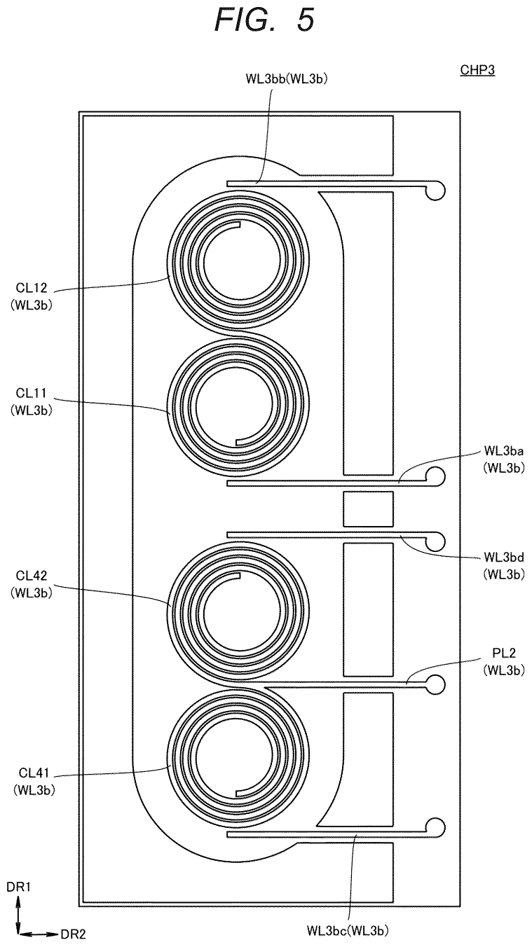

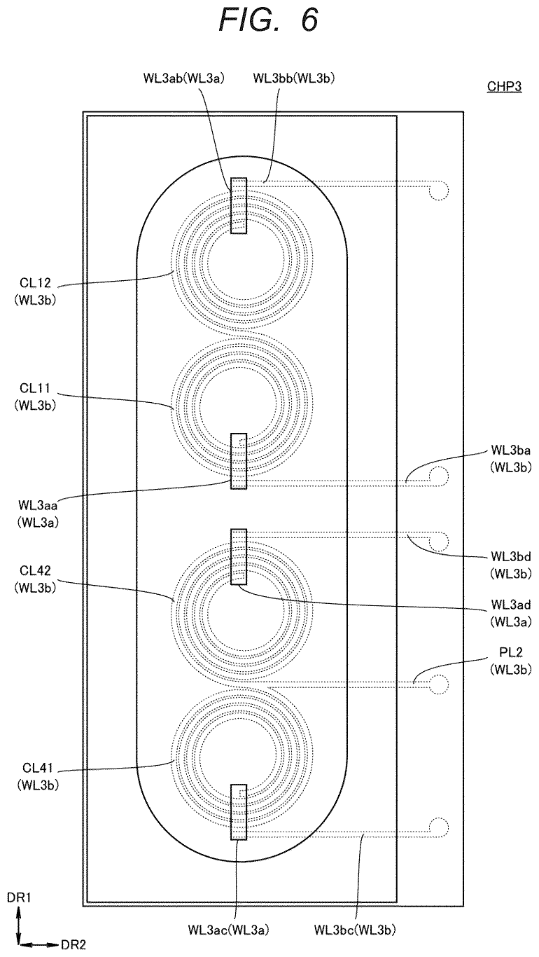

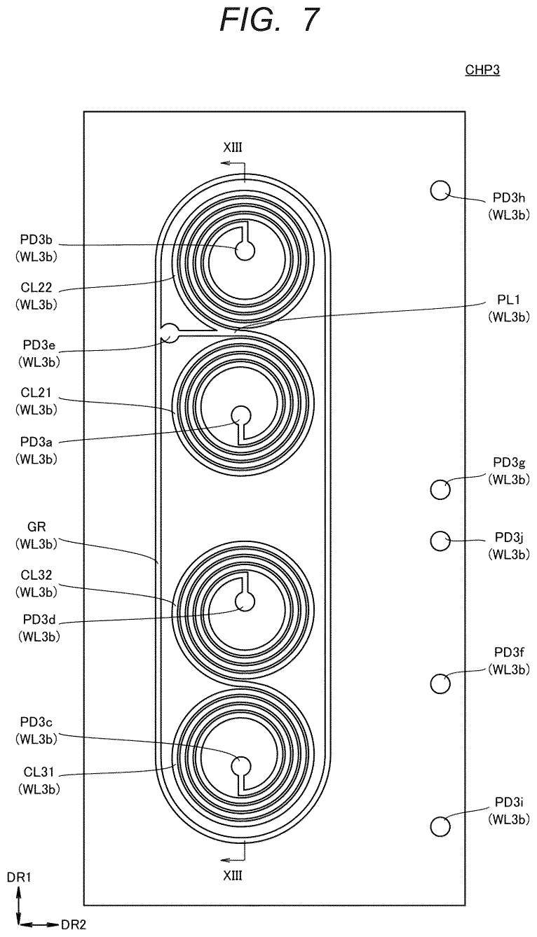

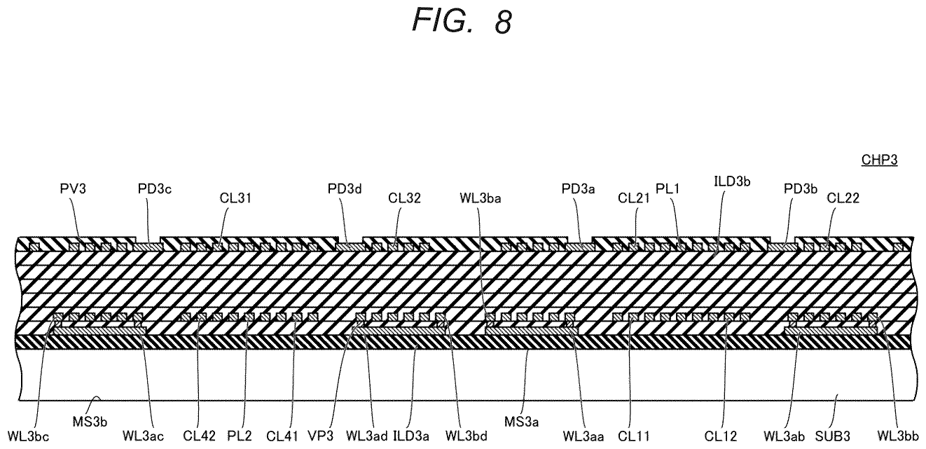

FIG. 5 is a first plan view of the semiconductor chip CHP3. FIG. 6 is a second plan view of the semiconductor chip CHP3. FIG. 7 is a third plan view of the semiconductor chip CHP3. FIG. 8 is a cross-sectional view along VIII-VIII in FIG. 7. As shown in FIGS. 5 to 8, the semiconductor chip CHP3 includes a semiconductor substrate SUB3, an interlayer insulating film ILD3a, a wiring layer WL3a, a plurality of interlayer insulating films ILD3b, a plurality of wiring layers WL3b, a via plug VP3, and a passivation film PV3.

The semiconductor substrate SUB3 has a main surface MS3a and a main surface MS3b. The main surface MS3a is the opposite surface of the main surface MS3a. The main surfaces MS3a and MS3b are end surfaces along the thickness direction of the semiconductor substrate SUB3. The semiconductor substrate SUB3 is formed of monocrystalline silicon. The main surface MS3a is composed of, for example, (110) plane, (111) plane, (112) plane, or (211) plane of monocrystalline silicon. However, the crystal face of the monocrystalline silicon constituting the main surface MS3a is not limited to these.

A lattice plane spacing parallel to the main surface MS3a in the semiconductor substrate SUB3 is smaller than a lattice plane spacing parallel to the main surface MS1a in the semiconductor substrate SUB1 and a lattice plane spacing parallel to the main surface MS2a in the semiconductor substrate SUB2. If this relationship is satisfied, it is possible to appropriately select the crystal face of the monocrystalline silicon forming the main surface MS1a, the crystal face of the monocrystalline silicon forming the main surface MS2a, and the crystal face of the monocrystalline silicon forming the main surface MS3a.

A lattice plane spacing of the (110) plane is 3.84 angstroms, a lattice plane spacing of the (111) plane is 3.14 angstroms, a lattice plane spacing of the (112) plane is 2.22 angstroms, and a lattice plane spacing of the (211) plane is 2.22 angstroms. On the other hand, a lattice plane spacing of the (100) plane is 5.43 angstroms.

A Young's modulus of the semiconductor substrate SUB1 in the direction parallel to the main surface MS3a is greater than A Young's modulus of the semiconductor substrate SUB1 in the direction parallel to the main surface MS1a and a Young's modulus of the semiconductor substrate SUB2 in the direction parallel to the main surface MS2a. A Young's modulus of monocrystalline silicon in the direction parallel to the (100) plane is 130 GPa. Also, a Young's modulus of monocrystalline silicon in the direction parallel to the (110) plane is 170 GPa, and a Young's modulus in the direction parallel to the (111) plane is 189 GPa.

The interlayer insulating film ILD3a is formed on the main surface MS3a. Although not shown, a contact hole CH3 is formed in the interlayer insulating film ILD3a. A contact plug CP3 (not shown) is embedded in the contact hole CH3. The contact plug CP3 is connected to the main surface MS3a. The interlayer insulating film ILD3a is formed of, for example, silicon oxide. The contact plug CP3 is formed of, for example, tungsten.

The wiring layer WL3a is formed on the interlayer insulating film ILD3a. Although not shown, the wiring layer WL3a is electrically connected to the contact plug CP3. The wiring layer WL3a is formed of, for example, aluminum or an aluminum alloy.

The plurality of interlayer insulating films ILD3b is laminated on the interlayer insulating film ILD3a. The plurality of interlayer insulating films ILD3b is formed of, for example, silicon oxide. The lowermost interlayer insulating film ILD3b covers the wiring layer WL3a. One wiring layer WL3b is formed on one interlayer insulating film ILD3b, and another interlayer insulating film ILD3b is formed on the one interlayer insulating film ILD3b so as to cover the one wiring layer WL3b. However, the uppermost wiring layer WL3b is not covered by the one or another interlayer insulating film ILD3b. One wiring layer WL3a and another wiring layer WL3b on an upper layer of the one wiring layer WL3a are electrically connected by the via plug VP3. The via plug VP3 is embedded in a via hole VH3 formed in the interlayer insulating film ILD3b. The plurality of wiring layers WL3b is formed of, for example, aluminum or an aluminum alloy. The via plug VP3 is formed of, for example, tungsten.

The uppermost wiring layer WL2b includes electrode pads PD3a, PD3b, PD3c, PD3d, PD3e, PD3f, PD3g, PD3h, PD3i, and PD3j.

The passivation film PV3 is formed on the uppermost interlayer insulating film ILD3b so as to cover the uppermost wiring layer WL3b. An opening is formed in the passivation film PV3. The electrode pads (electrode pads PD3a to PD3j) of the uppermost wiring layer WL3b are exposed from the opening of the passivation film PV3. The passivation film PV3 is formed of, for example, silicon nitride.

The lowermost wiring layer WL3b includes the transmitting coil CL1, the receiving coil CL4, and the lead-out wiring PL2. The lowermost wiring layer WL3b further includes wirings WL3ba, WL3bb, WL3bc, and WL3bd. The transmitting coil CL1 and the receiving coil CL4 are aligned along a first direction DR1 in plan view (when viewed from the normal direction of the main surface MS3a of the semiconductor chip CHP3).

The coils CL11 and CL12 are aligned along the first direction DR1 in plan view. The coils CL11 and CL12 are wound in a spiral shape in plan view. The coil CL11 is wound counterclockwise from the innermost circumference to the outermost circumference. The coil CL12 is wound clockwise from the outermost circumference to the innermost circumference. The end at the outermost circumference of the coil CL11 is connected to the end at the outermost circumference of the coil CL12. From another perspective, the coils CL11 and CL12 are in a serial aiding configuration.

The coils CL41 and CL42 are aligned along the first direction DR1 in plan view. The coils CL41 and CL42 are wound in a spiral shape in plan view. The coil CL41 is wound counterclockwise from the innermost circumference to the outermost circumference. The coil CL42 is wound clockwise from the outermost circumference to the innermost circumference. The end at the outermost circumference of the coil CL41 is connected to the end at the outermost circumference of the coil CL42 via one end of the lead-out wiring PL2. From another perspective, the coils CL41 and CL42 are in a serial aiding configuration.

The lead-out wiring PL2 extends along a second direction DR2. The second direction DR2 is perpendicular to the first direction DR1.

The wirings WL3ba, WL3bb, WL3bc, and WL3bd extend along the second direction DR2 in plan view. One end of the wiring WL3ba in the second direction DR2 and one end of the wiring WL3bb in the second direction DR2 are adjacent to the coils CL11 and CL12, respectively. One end of the wiring WL3bc in the second direction DR2 and one end of the wiring WL3bd in the second direction DR2 are adjacent to the coils CL41 and CL42, respectively.

The wiring layer WL3a includes wirings WL3aa, WL3ab, WL3ac, and WL3ad. The wirings WL3aa, WL3ab, WL3ac, and WL3ad extend along the first direction DR1 in plan view.

One end and the other end of the wiring WL3aa in the first direction DR1 overlap with one end of the wiring WL3ba and the end at the innermost circumference of the coil CL11, respectively. One end and the other end of the wiring WL3ab in the first direction DR1 overlap with one end of the wiring WL3bb and the end at the innermost circumference of the coil CL12, respectively. One end and the other end of the wiring WL3ac in the first direction DR1 overlap with one end of the wiring WL3bc and the end at the innermost circumference of the coil CL41, respectively. One end and the other end of the wiring WL3ad in the first direction DR1 overlap with one end of the wiring WL3bd and the end at the innermost circumference of the coil CL42, respectively.

One end and the other end of the wiring WL3aa in the first direction DR1 are electrically connected to one end of the wiring WL3ba and the end at the innermost circumference of the coil CL11 by the via plug VP3, respectively. One end and the other end of the wiring WL3ab in the first direction DR1 are electrically connected to one end of the wiring WL3bb and the end at the innermost circumference of the coil CL12 by the via plug VP3, respectively. One end and the other end of the wiring WL3ac in the first direction DR1 are electrically connected to one end of the wiring WL3bc and the end at the innermost circumference of the coil CL41 by the via plug VP3, respectively. One end and the other end of the wiring WL3ad in the first direction DR1 are electrically connected to one end of the wiring WL3bd and the end at the innermost circumference of the coil CL42 by the via plug VP3, respectively.

The uppermost wiring layer WL3b further includes the receiving coil CL2, the transmitting coil CL3, the lead-out wiring PL1, and a guard ring GR. The lead-out wiring PL1 extends along the second direction DR2.

The receiving coil CL2 and the transmitting coil CL3 are aligned along the first direction DR1 in plan view. The receiving coil CL2 and the transmitting coil CL3 each overlap with the transmitting coil CL1 and the receiving coil CL4, respectively, in plan view. That is, the coils CL21 and CL22 face the coils CL11 and CL12, respectively, with an insulating layer (the plurality of interlayer insulating films ILD3b) interposed, and the coils CL31 and CL32 face the coils CL41 and CL42, respectively, with an insulating layer (the plurality of interlayer insulating films ILD3b) interposed. From another perspective, the coils CL21 and CL22 are magnetically coupled to the coils CL11 and CL12, respectively. Similarly, the coils CL31 and CL32 are magnetically coupled to the coils CL41 and CL42, respectively.

The coils CL21 and CL22 are aligned along the first direction DR1 in plan view. The coils CL21 and CL22 are wound in a spiral shape in plan view. The coil CL21 is wound counterclockwise from the innermost circumference to the outermost circumference. The coil CL22 is wound clockwise from the outermost circumference to the innermost circumference. The end at the outermost circumference of the coil CL21 is connected to the end at the outermost circumference of the coil CL22 via one end of the lead-out wiring PL1. From another perspective, the coils CL21 and CL22 are configured in series aiding.

The coils CL31 and CL32 are aligned along the first direction DR1 in plan view. The coils CL31 and CL32 are wound in a spiral shape in plan view. The coil CL31 is wound counterclockwise from the innermost circumference to the outermost circumference. The coil CL32 is wound clockwise from the outermost circumference to the innermost circumference. The end at the outermost circumference of the coil CL31 is connected to the end at the outermost circumference of the coil CL32. From another perspective, the coils CL31 and CL32 are configured in series aiding.

The electrode pad PD3a and the electrode pad PD3b are connected to the ends at the innermost circumference of the coils CL21 and CL22, respectively. The electrode pad PD3c and the electrode pad PD3d are connected to the ends at the innermost circumference of the coils CL31 and CL32, respectively.

The electrode pad PD3e is connected to one end of the lead-out wiring PL1. The electrode pad PD3f overlaps with the other end of the lead-out wiring PL2 in plan view. Although not shown, the electrode pad PD3f is electrically connected to the other end of the lead-out wiring PL2 via multiple wiring layers WL3b and the via plug VP3.

The electrode pad PD3g and the electrode pad PD3h overlap with other ends of a wiring WL2ba and a wiring WL2bb, respectively, in plan view. Although not shown, the electrode pad PD3g and the electrode pad PD3h are electrically connected to the other ends of the wiring WL2ba and the wiring WL2bb, respectively, via multiple wiring layers WL2b and the via plug VP3. Thus, the electrode pad PD3g and the electrode pad PD3h are electrically connected to the transformer TR1 (transmitting coil CL1).

The electrode pad PD3i and the electrode pad PD3j overlap with other ends of a wiring WL2bc and a wiring WL2bd, respectively, in plan view. Although not shown, the electrode pad PD3i and the electrode pad PD3j are electrically connected to the other ends of the wiring WL2bc and the wiring WL2bd, respectively, via multiple wiring layers WL2b and the via plug VP3. Thus, the electrode pad PD3i and the electrode pad PD3j are electrically connected to the transformer TR2 (receiving coil CL4).

The guard ring GR surrounds the receiving coil CL2 and the transmitting coil CL3 in plan view. The electrode pad PD3e is connected to the guard ring GR. A reference potential is applied to the electrode pad PD3e. Therefore, the same reference potential is applied to the guard ring GR. Note that a higher reference potential than that of the electrode pad PD3e is applied to the electrode pad PD3f.

### (Manufacturing Method of Semiconductor Chip CHP1)

The manufacturing method of the semiconductor chip CHP1 is explained below.

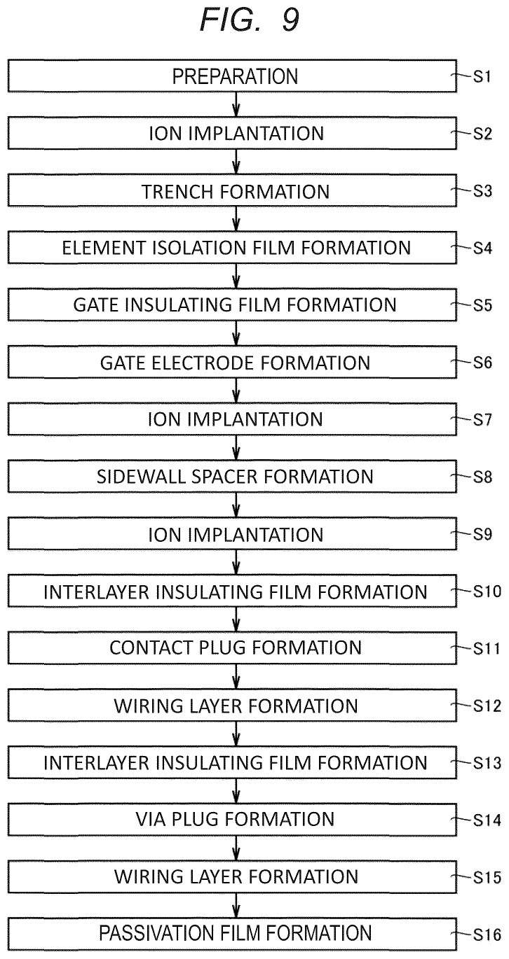

FIG. 9 is a flow chart for manufacturing the semiconductor chip CHP1. As shown in FIG. 9, the manufacturing method of the semiconductor chip CHP1 includes a preparation step S1, an ion implantation step S2, a trench formation step S3, an element isolation film formation step S4, a gate insulating film formation step S5, a gate electrode formation step S6, an ion implantation step S7, a sidewall spacer formation step S8, and an ion implantation step S9. The manufacturing method of the semiconductor chip CHP3 further includes an interlayer insulating film formation step S10, a contact plug formation step S11, a wiring layer formation step S12, an interlayer insulating film formation step S13, a via plug formation step S14, a wiring layer formation step S15, and a passivation film formation step S16.

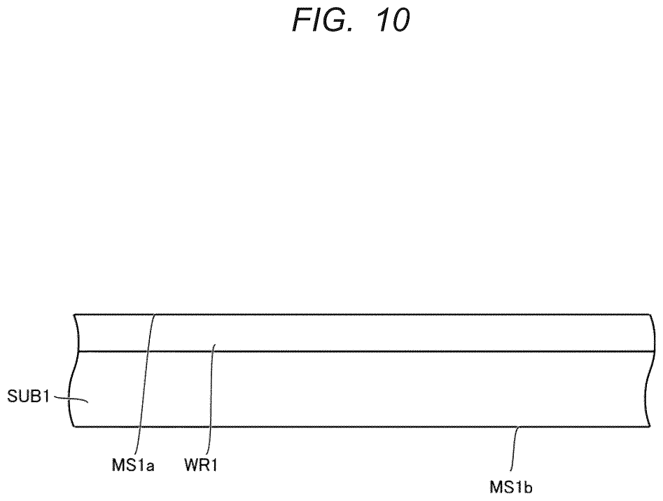

In the preparation step S1, the semiconductor substrate SUB1 is prepared. FIG. 10 is a cross-sectional view for explaining the ion implantation step S2. As shown in FIG. 10, in the ion implantation step S2, the well region WR1 is formed by ion implantation.

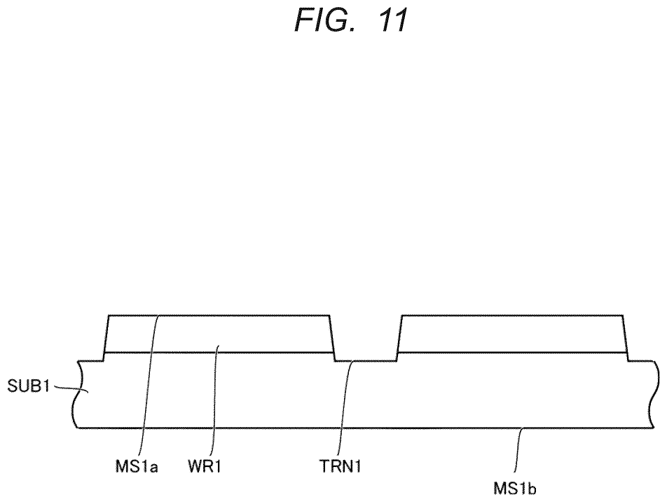

FIG. 11 is a cross-sectional view for explaining the trench formation step S3. As shown in FIG. 11, in the trench formation step S3, the trench TRN1 is formed on the main surface MS1a. In the trench formation step S3, first, a hard mask is formed on the main surface MS1a. The hard mask is, for example, a laminated film of an oxide film and a nitride film. Second, the hard mask is patterned. The patterning of the hard mask is performed, for example, by dry etching using a resist pattern formed on the hard mask. Third, dry etching is performed using the hard mask as a mask. As a result, the trench TRN1 is formed.

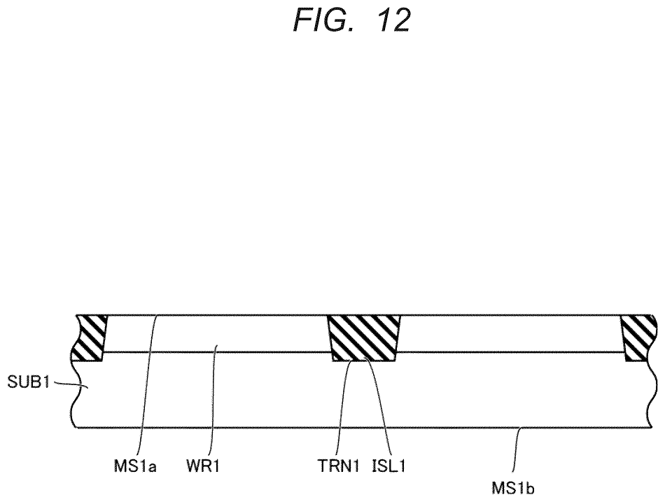

FIG. 12 is a cross-sectional view for explaining the element isolation film formation step S4. As shown in FIG. 12, in the element isolation film formation step S4, the element isolation film ISL1 is embedded in the trench TRN1. In the element isolation film formation step S4, first, the constituent material of the element isolation film ISL1 is embedded in the trench TRN1 by, for example, a CVD (Chemical Vapor Deposition) method. Second, the constituent material of the element isolation film ISL1 protruding from the trench TRN1 is removed by, for example, a CMP (Chemical Mechanical Polishing) method. At this time, the hard mask is also removed. As a result, the element isolation film ISL1 is formed.

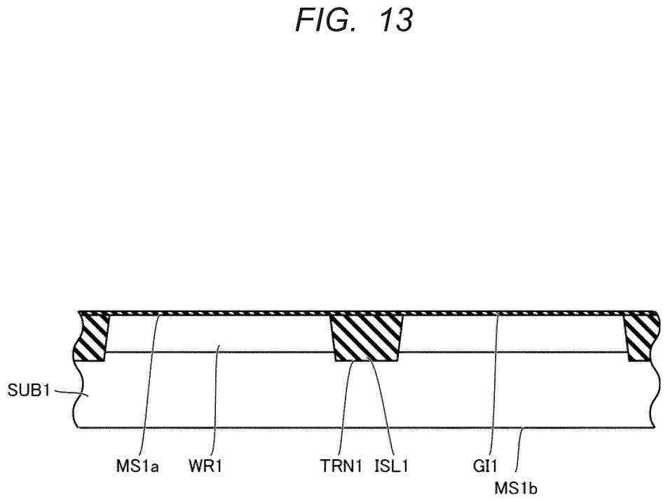

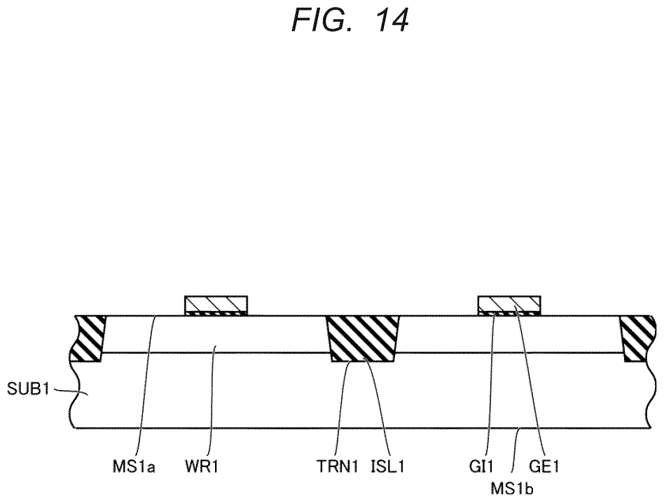

FIG. 13 is a cross-sectional view for explaining the gate insulating film formation step S5. As shown in FIG. 13, in the gate insulating film formation step S5, the gate insulating film GI1 is formed on the main surface MS1a by, for example, thermal oxidation of the main surface MS1a. FIG. 14 is a cross-sectional view for explaining the gate electrode formation step S6. As shown in FIG. 14, in the gate electrode formation step S6, the gate electrode GE1 is formed on the gate insulating film GI1. In the gate electrode formation step S6, first, the constituent material of the gate electrode GEL is deposited on the gate insulating film GI1 by, for example, a CVD method. Second, the constituent material of the deposited gate electrode GE1 is patterned by etching using a resist pattern formed on the gate electrode GE1 as a mask. As a result, the gate electrode GE1 is formed.

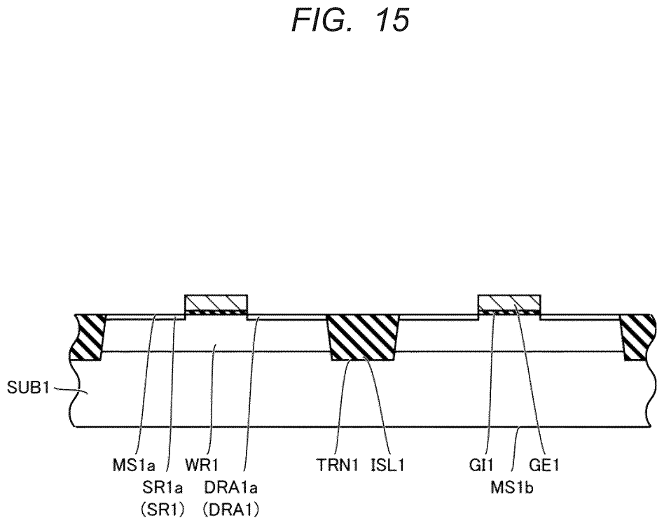

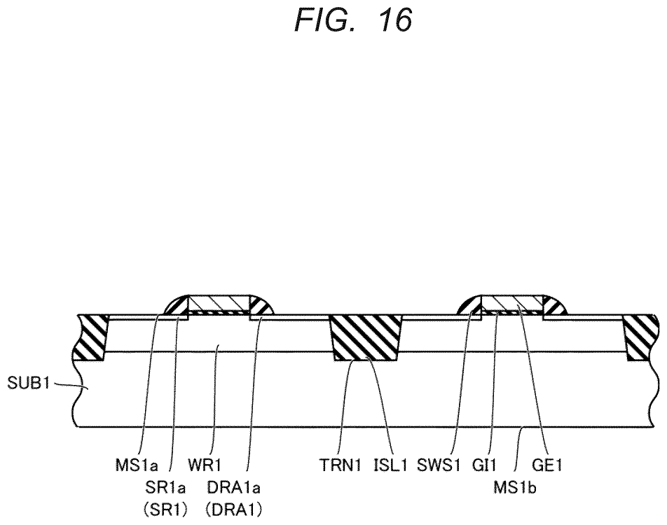

FIG. 15 is a cross-sectional view for explaining the ion implantation step S7. In the ion implantation step S7, as shown in FIG. 15, the first portion SR1a and the first portion DRA1a are formed by ion implantation. FIG. 16 is a cross-sectional view for explaining the sidewall spacer formation step S8. As shown in FIG. 16, in the sidewall spacer formation step S8, the sidewall spacers SWS1 are formed on the main surface MS1a so as to contact the side surfaces of the gate insulating film GI1 and the gate electrode GE1. In the sidewall spacer formation step S8, first, the constituent material of the sidewall spacers SWS1 are deposited by, for example, a CVD method so as to cover the gate insulating film GI1 and the gate electrode GE1. Second, the constituent material of the deposited sidewall spacers SWS1 is etched back. As a result, the sidewall spacer SWS1 is formed.

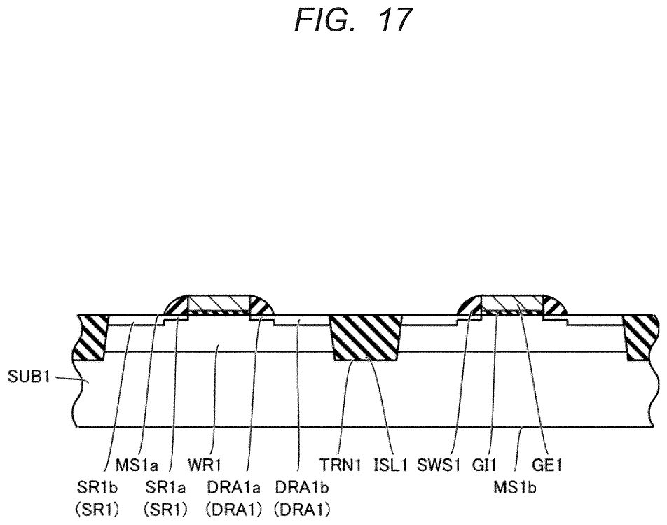

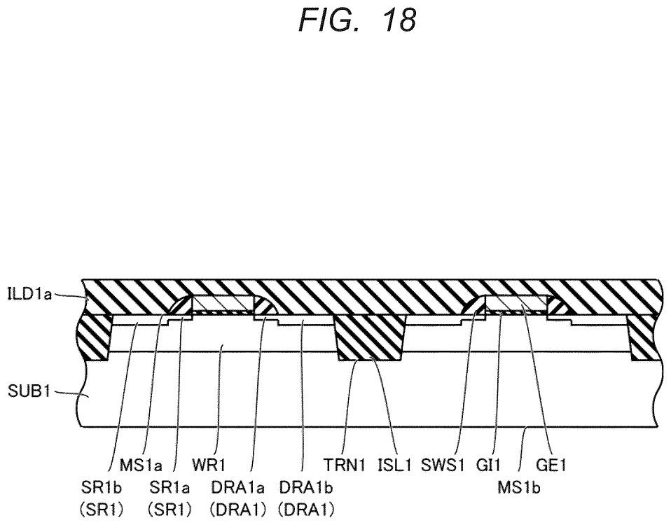

FIG. 17 is a cross-sectional view for explaining the ion implantation step S9. In the ion implantation step S9, as shown in FIG. 17, the second portion SR1b and the second portion DRA1b are formed by ion implantation. FIG. 18 is a cross-sectional view for explaining the interlayer insulating film formation step S10. As shown in FIG. 18, in the interlayer insulating film formation step S10, the interlayer insulating film ILD1a is formed on the main surface MS1a so as to cover the gate electrode GE1 and the sidewall spacers SWS1. In the interlayer insulating film formation step S10, first, the constituent material of the interlayer insulating film ILD1a is deposited by, for example, a CVD method so as to cover the gate electrode GE1 and the sidewall spacers SWS1. Second, the surface of the deposited interlayer insulating film ILD1a is planarized by, for example, a CMP method. As a result, the interlayer insulating film ILD1a is formed.

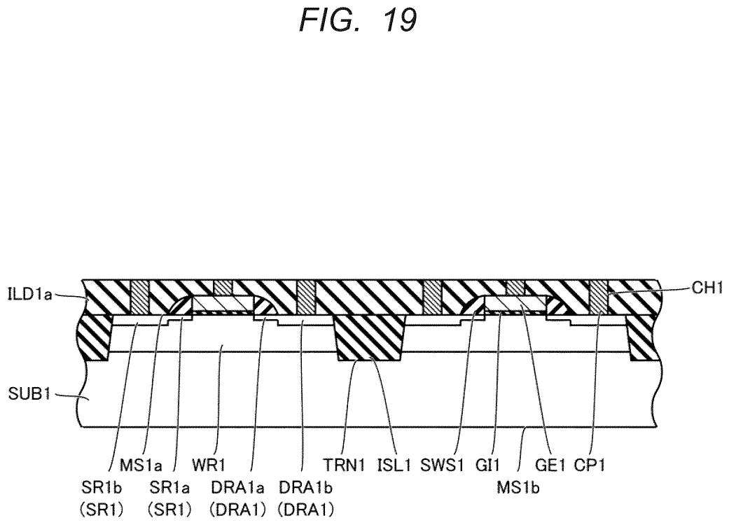

FIG. 19 is a cross-sectional view for explaining the contact plug formation step S11. As shown in FIG. 19, in the contact plug formation step S11, the contact plug CP1 is embedded in the interlayer insulating film ILD1a. In the contact plug formation step S11, first, the contact hole CH1 is formed by etching the interlayer insulating film ILD1a using a resist pattern formed on the interlayer insulating film ILD1a as a mask. Second, the constituent material of the contact plug CP1 is embedded in the contact plug CP1 by, for example, a CVD method. Third, the constituent material of the contact plug CP1 protruding from the contact hole CH1 is removed by, for example, a CMP method. As a result, the contact plug CP1 is formed.

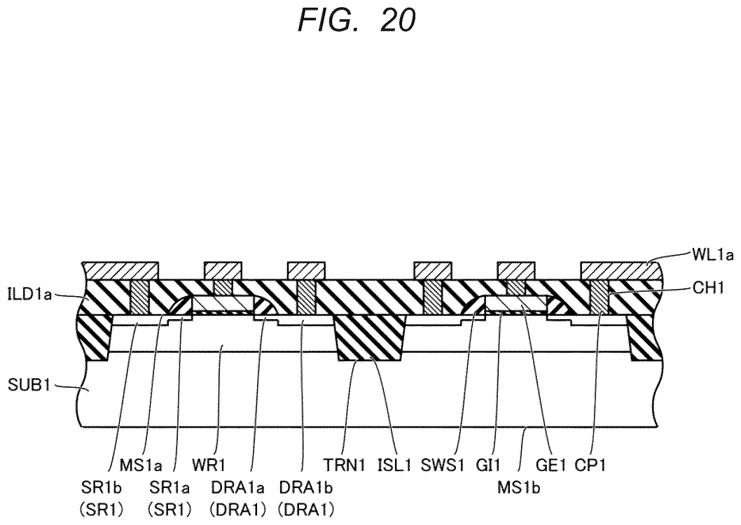

FIG. 20 is a cross-sectional view for explaining the wiring layer formation step S12. As shown in FIG. 20, in the wiring layer formation step S12, the wiring layer WL1a is formed on the interlayer insulating film ILD1a. In the wiring layer formation step S12, first, the constituent material of the wiring layer WL1a is deposited on the interlayer insulating film ILD1a by, for example, a sputtering method. Second, a resist pattern is formed on the constituent material of the deposited wiring layer WL1a. Third, the constituent material of the wiring layer WL1a is etched using the resist pattern as a mask. As a result, the wiring layer WL1a is formed.

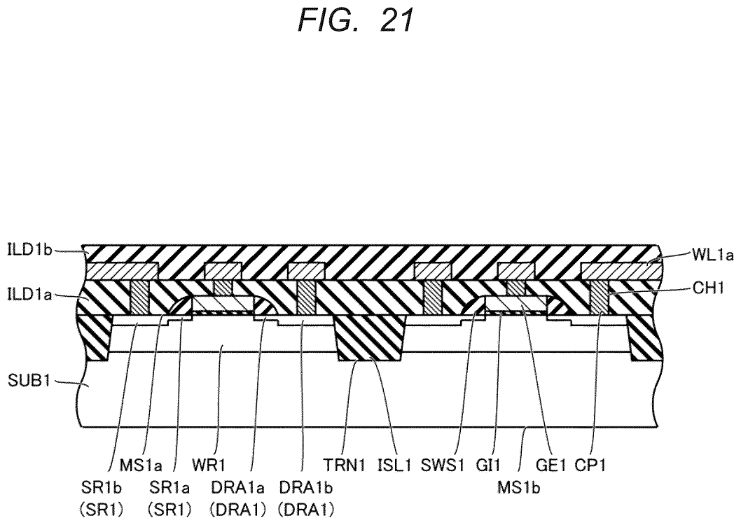

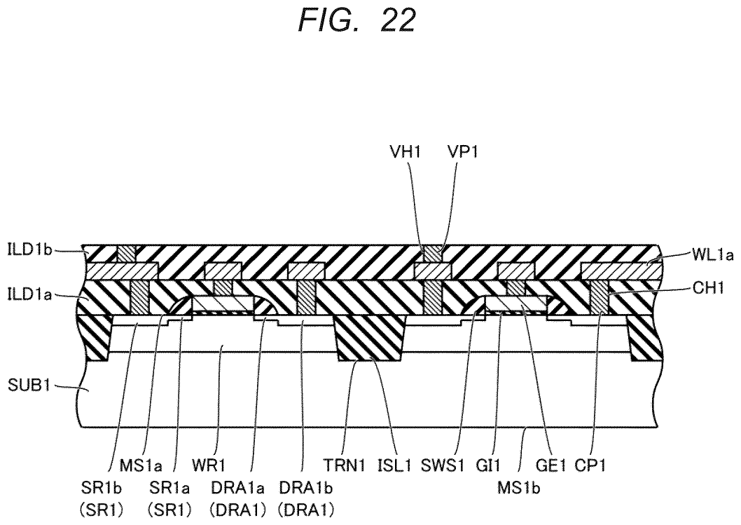

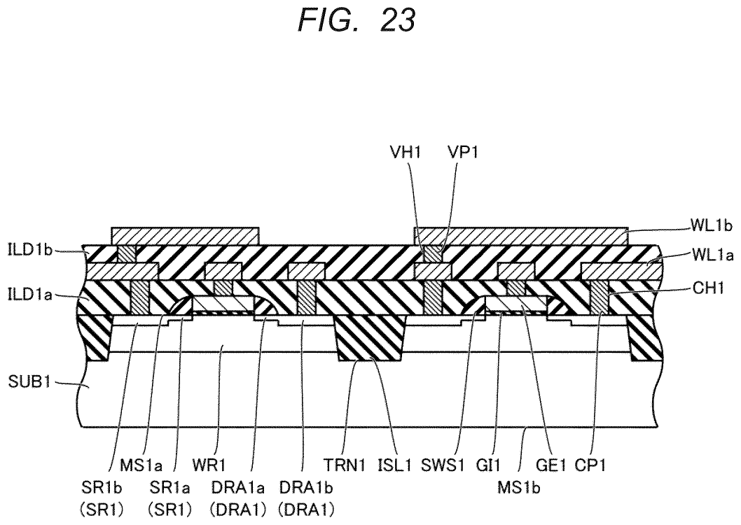

FIG. 21 is a cross-sectional view for explaining the interlayer insulating film formation step S13. As shown in FIG. 21, in the interlayer insulating film formation step S13, the interlayer insulating film ILD1b is formed on the interlayer insulating film ILD1a so as to cover the wiring layer WL1a by the same method as the interlayer insulating film formation step S10. FIG. 22 is a cross-sectional view for explaining the via plug formation step S14. As shown in FIG. 22, in the via plug formation step S14, the via hole VH1 is formed in the interlayer insulating film ILD1b, and the via plug VP1 is embedded in the via hole VH1 by the same method as the contact plug formation step S11. FIG. 23 is a cross-sectional view for explaining the wiring layer formation step S15. As shown in FIG. 23, in the wiring layer formation step S15, the wiring layer WL1b is formed on the interlayer insulating film ILD1b by the same method as the wiring layer formation step S12. Thereafter, the interlayer insulating film formation step S13, the via plug formation step S14, and the wiring layer formation step S15 are sequentially repeated until the uppermost wiring layer WL1b is formed.

In the passivation film formation step S16, the passivation film PV1 is formed on the uppermost interlayer insulating film ILD1b so as to cover the uppermost wiring layer WL1b. In the passivation film formation step S16, first, the constituent material of the passivation film PV1 is deposited on the uppermost interlayer insulating film ILD1b so as to cover the uppermost wiring layer WL1b. Second, a resist pattern is formed on the constituent material of the passivation film PV1. Third, an opening is formed to expose the electrode pad PD1 by etching the constituent material of the passivation film PV1 using the resist pattern as a mask. As a result, the structure of the semiconductor chip CHP1 shown in FIG. 3 is formed.

### (Manufacturing Method of Semiconductor Chips CHP2 and CHP3)

The manufacturing method of the semiconductor chips CHP2 and CHP3 is explained below.

The manufacturing method of the semiconductor chip CHP2 is the same as the manufacturing method of the semiconductor chip CHP1. The manufacturing method of the semiconductor chip CHP3 is the same as the manufacturing method of the semiconductor chip CHP1. However, in the manufacturing method of the semiconductor chip CHP3, the ion implantation step S2, the trench formation step S3, the element isolation film formation step S4, the gate insulating film formation step S5, the gate electrode formation step S6, the ion implantation step S7, the sidewall spacer formation step S8, and the ion implantation step S9 are not performed.

### (Effect of Semiconductor Device DEV)

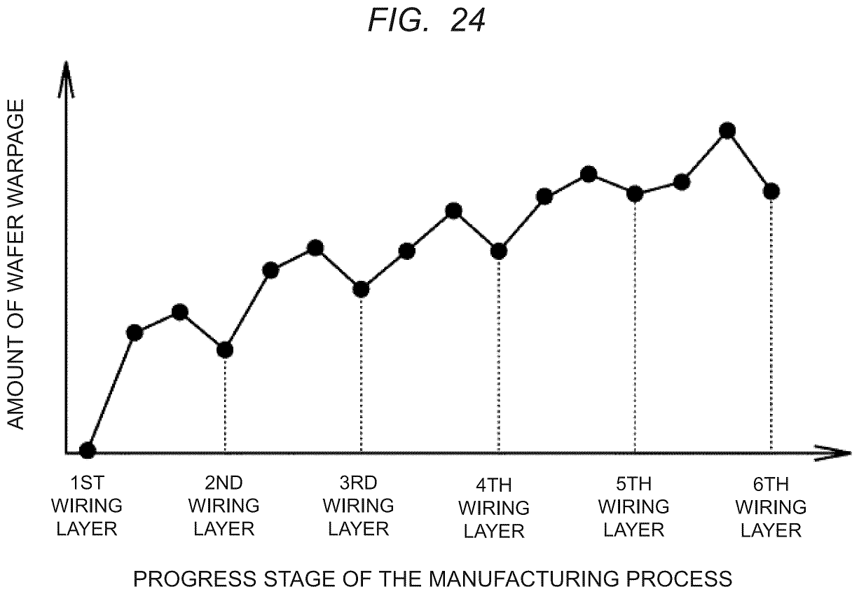

FIG. 24 is a schematic graph showing the relationship between a progress stage of the manufacturing process and an amount of wafer warpage in the semiconductor chip CHP3. As shown in FIG. 24, although the amount of wafer warpage decreases each time a wiring layer is formed, the overall amount of wafer warpage increases as the manufacturing process progresses. In the semiconductor chip CHP3, compared to the semiconductor chips CHP1 and CHP2, the area occupied by the wiring layer is smaller in plan view, so the correction of warpage accompanying the formation of the wiring layer is weaker, and the amount of wafer warpage tends to increase.

In this regard, in the semiconductor chip CHP3, the lattice plane spacing parallel to the main surface MS3a of the semiconductor substrate SUB3 is smaller than the lattice plane spacing parallel to the main surface MS1a of the semiconductor substrate SUB1 and the lattice plane spacing parallel to the main surface MS2a of the semiconductor substrate SUB2. As a result, in the semiconductor chip CHP3, the Young's modulus of the semiconductor substrate SUB1 in the direction parallel to the main surface MS3a is greater than the Young's modulus of the semiconductor substrate SUB1 in the direction parallel to the main surface MS1a and the Young's modulus of the semiconductor substrate SUB2 in the direction parallel to the main surface MS2a, thereby suppressing warpage.

In the semiconductor chip CHP1 (semiconductor chip CHP2), a transistor, which is an active element, is formed on the main surface MS1a (main surface MS2a), so it is preferable that the main surface MS1a (main surface MS2a) is a crystal face with high electron mobility, such as a (100) plane. On the other hand, in the semiconductor chip CHP3, since no transistor is formed on the main surface MS3a and passive elements (transformer TR1 and transformer TR2) are formed above the main surface MS3a, it is not necessary for the main surface MS3a to be a crystal face with high electron mobility. Thus, according to the semiconductor device DEV, it is possible to maintain electrical characteristics while suppressing warpage of the semiconductor chip CHP3.

To improve the breakdown voltage in the semiconductor chip CHP3, it is effective to increase a thickness of the insulating layer between the transmitting coil CL1 and the receiving coil CL2 (between the transmitting coil CL3 and the receiving coil CL4). However, increasing the thickness of this insulating layer (increasing the number of interlayer insulating films ILD3b stacked) results in greater warpage. In the semiconductor chip CHP3, since the Young's modulus of the semiconductor substrate SUB3 in the direction parallel to the main surface MS3a is high, it is less prone to warpage even if the thickness of this insulating layer is increased, making it possible to improve the breakdown voltage between the transmitting coil CL1 and the receiving coil CL2 (between the transmitting coil CL3 and the receiving coil CL4).

### First Modified Example

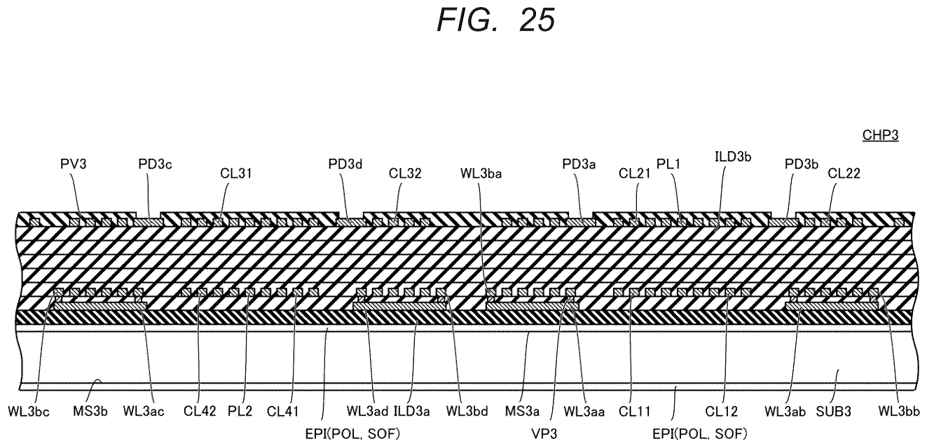

FIG. 25 is a cross-sectional view of the semiconductor chip CHP3 included in the semiconductor device DEV according to the first modified example. As shown in FIG. 25, the semiconductor chip CHP3 may further include an epitaxial layer EPI. The epitaxial layer EPI may be formed on at least one of the main surface MS3a or the main surface MS3b. Alternatively, a polysilicon layer POL may be formed instead of the epitaxial layer EPI. Furthermore, a silicon oxide film SOF may be formed instead of the epitaxial layer EPI. The silicon oxide film SOF is, for example, a film formed by oxidizing a polysilicon film. By forming the epitaxial layer EPI, the polysilicon layer POL, or the silicon oxide film SOF, the semiconductor substrate SUB3 becomes substantially thicker, which allows for further reduction of warping.

### Second Modified Example

In the above, the case where the transformer TR1 (transformer TR2) is composed of coils facing each other with the insulating layer interposed was shown, but the transformer TR1 (transformer TR2) is not limited to this. For example, instead of the transmitting coil CL1 (transmitting coil CL3) and the receiving coil CL2 (receiving coil CL4), the transformer TR1 (transformer TR2) may be configured as a capacitor composed of a pair of electrode plates facing each other via the insulating layer.

### Second Embodiment

A semiconductor package according to a second embodiment will be described. The semiconductor package according to the second embodiment is referred to as the semiconductor package PKG.

### (Configuration of Semiconductor Package PKG)

A configuration of the semiconductor package PKG will be described below.

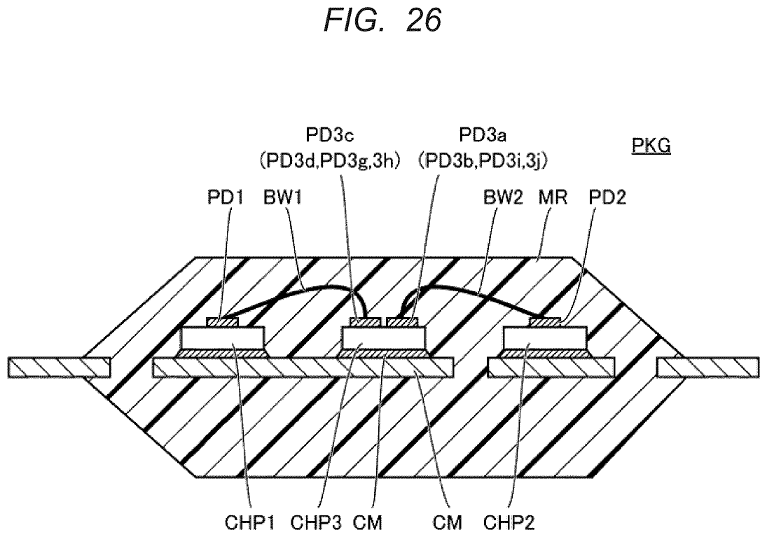

FIG. 26 is a cross-sectional view of the semiconductor package PKG. As shown in FIG. 26, the semiconductor package PKG includes a lead frame LF, semiconductor chips CHP1, CHP2, and CHP3, bonding wires BW1 and BW2, and a sealing resin MR.

The semiconductor chip CHP1 is arranged on the lead frame LF such that a main surface MS1b faces the lead frame LF with the bonding material CM interposed. Similarly, the semiconductor chip CHP2 is arranged on the lead frame LF such that the main surface MS2b faces the lead frame LF with the bonding material CM interposed, and the semiconductor chip CHP3 is arranged on the lead frame LF such that the main surface MS3b faces the lead frame LF with the bonding material CM interposed. It is preferable that thicknesses of the semiconductor chips CHP1, CHP2, and CHP3 are equal to each other. If the thicknesses of two of the semiconductor chips CHP1, CHP2, and CHP3 are within ±10 percent of the other one, they can be considered equal.

Height positions of a surface of the electrode pad PD1, the electrode pad PD2, and the electrode pads of the semiconductor chip CHP3 (electrode pads PD3a, PD3b, PD3c, PD3d, PD3g, PD3h, PD3i, PD3j) are preferably equal to each other. If the height positions of the surface of two of the electrode pad PD1, the electrode pad PD2, and the electrode pads of the semiconductor chip CHP3 are within ±30 micrometers of the other one, they can be considered equal.

The bonding wire BW1 is electrically connected at one end to the electrode pads (electrode pads PD3c, PD3d, PD3g, PD3h) of the semiconductor chip CHP3 and at the other end to the electrode pad PD1. The bonding wire BW2 is electrically connected at one end to the electrode pads PD3a, PD3b, PD3i, PD3j of the semiconductor chip CHP3 and at the other end to the electrode pad PD2. Thus, the semiconductor package PKG functions as a semiconductor device DEV.

The sealing resin MR seals the lead frame LF, the bonding wires BW1 and BW2, and the semiconductor chips CHP1, CHP2, and CHP3. However, the terminal portion of the lead frame LF is exposed from a sealing resin MF.

### (Effect of Semiconductor Package PKG)

The effect of the semiconductor package PKG will be described below.

In the semiconductor chip CHP3, since a Young's modulus of a semiconductor substrate SUB1 in the direction parallel to a main surface MS3a is greater than a Young's modulus of the semiconductor substrate SUB1 in the direction parallel to the main surface MS1a and a Young's modulus of the semiconductor substrate SUB2 in the direction parallel to a main surface MS2a, it is not necessary to make the semiconductor chip CHP3 thicker compared to the semiconductor chips CHP1 and CHP2 that suppress warping, and it is possible to make the thickness of the semiconductor chip CHP3 equal to the thickness of the semiconductor chips CHP1 and CHP2. Therefore, according to the semiconductor package PKG, it is possible to reduce a thickness of the package.

Moreover, in the semiconductor package PKG, as a result of making the thickness of the semiconductor chip CHP3 equal to the thickness of the semiconductor chips CHP1 and CHP2, it is possible to make the height positions of the surface of the electrode pad PD1, the electrode pad PD2, and the electrode pads of the semiconductor chip CHP3 equal to each other. Therefore, it is possible to easily perform wire bonding with the bonding wires BW1 and BW2.

### Third Embodiment

An inverter system according to the third embodiment will be described. The inverter system according to the third embodiment is referred to as an inverter system INVS.

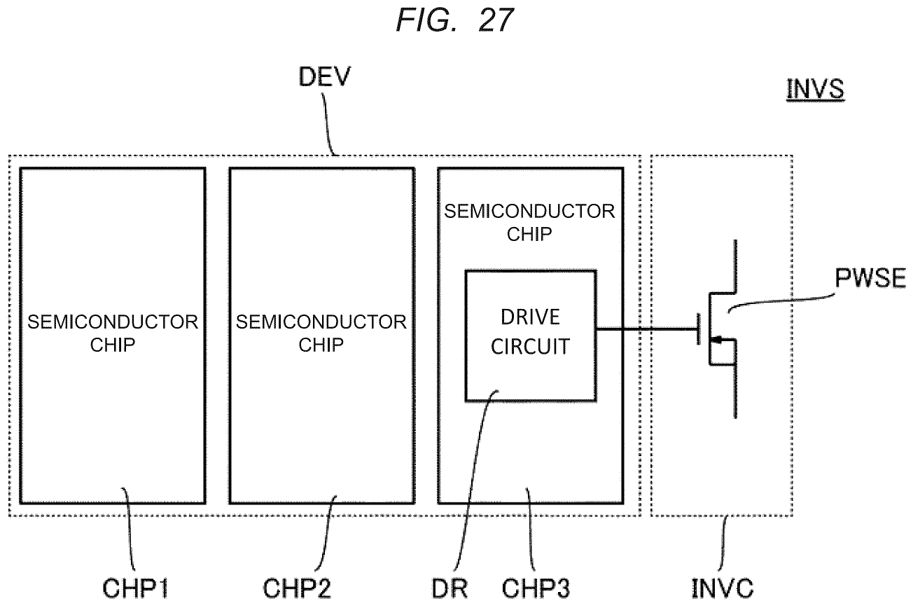

FIG. 27 is a schematic diagram of the inverter system INVS. As shown in FIG. 27, the inverter system INVS includes an inverter circuit INVC and a semiconductor device DEV. The inverter circuit INVC includes a power semiconductor element PWSE. The power semiconductor element PWSE is, for example, an IGBT (Insulated Gate Bipolar Transistor). However, the power semiconductor element PWSE is not limited to this.

A control terminal (gate electrode) of the power semiconductor element PWSE is connected to the drive circuit DR of the semiconductor device DEV (semiconductor chip CHP2), and the on-off of the power semiconductor element PWSE is controlled by a signal generated in the drive circuit DR, and the switching operation of the inverter circuit INVC is performed.

Although the invention made by the present inventors has been described in detail based on the embodiments, it is needless to say that the present invention is not limited to the above-described embodiments and can be variously modified without departing from the gist thereof.

What is claimed is:

1. A semiconductor device comprising:
a first semiconductor chip;
a second semiconductor chip; and
a third semiconductor chip; wherein
signal transmission and reception between the first semiconductor chip and the second semiconductor chip are performed by non-contact communication between different potentials in the third semiconductor chip,
the first semiconductor chip includes a first semiconductor substrate and a first active element,
the first semiconductor substrate has a first main surface,
the first active element is formed on the first main surface,
the second semiconductor chip includes a second semiconductor substrate and a second active element,
the second semiconductor substrate has a second main surface,
the second active element is formed on the second main surface,
the third semiconductor chip includes a third semiconductor substrate and a passive element,
the third semiconductor substrate has a third main surface,
the passive element is formed above the third main surface,
each of the first semiconductor substrate, the second semiconductor substrate, and the third semiconductor substrate is formed of monocrystalline silicon, and
a lattice plane spacing parallel to the third main surface in the third semiconductor substrate is smaller than a lattice plane spacing parallel to the parallel to the first main surface in the first semiconductor substrate and a lattice plane spacing parallel to the second main surface in the second semiconductor substrate.

2. The semiconductor device according to claim 1, wherein
a crystal face parallel to the third main surface in the third semiconductor substrate is different from a crystal face parallel to the first main surface in the first semiconductor substrate and a crystal face parallel to the second main surface in the second semiconductor substrate.

3. The semiconductor device according to claim 2, wherein
the crystal face parallel to the first main surface in the first semiconductor substrate and the crystal face parallel to the second main surface in the second semiconductor substrate are (100) crystal face, and
the crystal face parallel to the third main surface in the third semiconductor substrate is (111) crystal face or (110) crystal face.

4. The semiconductor device according to claim 1, wherein
the first active element and the second active element are transistors, and
the passive element is a transformer that performs non-contact communication between different potentials.

5. The semiconductor device according to claim 4, wherein
the transformer includes a first coil and a second coil, and an insulating layer, and
the first coil and the second coil are magnetically coupled to each other by placed opposite each other via the insulating layer.

6. The semiconductor device according to claim 4, wherein
the transformer includes a first electrode plate and a second electrode plate, and an insulating layer,
and the first electrode plate and the second electrode plate are capacitively coupled to each other by placed opposite each other via the insulating layer.

7. The semiconductor device according to claim 1, wherein
a thickness of the first semiconductor chip, a thickness of the second semiconductor chip, and a thickness of the third semiconductor chip are equal to each other.

8. The semiconductor device according to claim 7, wherein
the thickness of the first semiconductor chip, the thickness of the second semiconductor chip, and the thickness of the third semiconductor chip are 150 micrometers or more and 450 micrometers or less.

9. The semiconductor device according to claim 1, wherein
the third semiconductor substrate has a fourth main surface opposite to the third main surface,
the third semiconductor chip further includes an epitaxial layer, and
the epitaxial layer is formed on at least one of the third main surface and the fourth main surface.

10. The semiconductor device according to claim 1, wherein
the third semiconductor substrate has a fourth main surface opposite to the third main surface,
the third semiconductor chip further includes a polycrystalline silicon layer, and
the polycrystalline silicon layer is formed on at least one of the third main surface and the fourth main surface.

11. The semiconductor device according to claim 1, wherein
the third semiconductor substrate has a fourth main surface opposite to the third main surface,
the third semiconductor chip further includes a silicon oxide film, and
the silicon oxide film is formed on at least one of the third main surface and the fourth main surface.

12. The semiconductor device according to claim 1, wherein
a Young's modulus of the third semiconductor substrate in a direction parallel to the third main surface is greater than a Young's modulus of the first semiconductor substrate in a direction parallel to the first main surface and a Young's modulus of the second semiconductor substrate in a direction parallel to the second main surface.

13. A semiconductor package comprising:
a first semiconductor chip,
a second semiconductor chip,
a third semiconductor chip,
a first bonding wire, and
a second bonding wire, wherein
the first semiconductor chip includes a first circuit and a first electrode pad electrically connected to the first circuit,
the first circuit includes a first active element,
the second semiconductor chip includes a second circuit and a second electrode pad electrically connected to the second circuit,
the second circuit includes a second active element,
the third semiconductor chip includes a transformer and a third electrode pad and a fourth electrode pad electrically connected to the transformer,
the transformer includes a passive element,
the first bonding wire electrically connects the first electrode pad and the third electrode pad,
the second bonding wire electrically connects the second electrode pad and the fourth electrode pad, and
height positions of a surface of the first electrode pad, a surface of the second electrode pad, a surface of the third electrode pad, and a surface of the fourth electrode pad are equal to each other.

14. An inverter system comprising:
an inverter circuit,
a first semiconductor chip,
a second semiconductor chip, and
a third semiconductor chip, wherein
the inverter circuit includes a power semiconductor element,
the first semiconductor chip includes a first semiconductor substrate and a first circuit,
the first semiconductor substrate has a first main surface,
the first circuit includes a first active element,
the first active element is formed on the first main surface,
the second semiconductor chip includes a second semiconductor substrate and a second circuit and a third circuit,
the second semiconductor substrate has a second main surface,
the second circuit and the third circuit include a second active element,
the second active element is formed on the second main surface,
the third semiconductor chip includes a third semiconductor substrate and a transformer,
the third semiconductor substrate has a third main surface,
the transformer includes a passive element,
the passive element is formed above the third main surface, and
a signal transmitted from the first semiconductor chip to the second semiconductor chip is performed by non-contact communication between different potentials in in the transformer,
the third circuit drives the power semiconductor element based on the signal transmitted to the second circuit,
each of the first semiconductor substrate, the second semiconductor substrate, and the third semiconductor substrate is formed of monocrystalline silicon,
a lattice plane spacing parallel to the third main surface in the third semiconductor substrate is smaller than a lattice plane spacing parallel to the parallel to the first main surface in the first semiconductor substrate and a lattice plane spacing parallel to the second main surface in the second semiconductor substrate.
